(19) United States
(12) Patent Application Publication
(10) Pub. No.: US 2024/0025052 A1
(43) Pub. Date: Jan. 25, 2024

(54) SUBSTRATE HOLDING HAND AND SUBSTRATE CONVEYING ROBOT

(71) Applicant: KAWASAKI JUKOGYO KABUSHIKI KAISHA, Kobe-shi, Hyogo (JP)

(72) Inventor: Ippei SHIMIZU, Kobe-shi (JP)

(73) Assignee: KAWASAKI JUKOGYO KABUSHIKI KAISHA, Kobe-shi, Hyogo (JP)

(21) Appl. No.: 18/024,686

(22) PCT Filed: Nov. 2, 2020
(86) PCT No.: PCT/JP2020/041028

§ 371 Date: Mar. 3, 2023

(30) Foreign Application Priority Data
Sep. 3, 2020 (JP) 2020-148492

(51) Int. Cl. B25J 11/00; B25J 13/08

(52) U.S. Cl. CPC B25J 11/0095; B25J 13/088

(57) ABSTRACT

A substrate holding hand includes a frame, a blade supported by the frame, a pair of front supports provided on a tip end side of the blade to support a substrate, and a pair of rear supports provided on a base end side of the blade to support the substrate. The frame, the pair of front supports, and the pair of rear supports are provided in a V-shape.

### TECHNICAL FIELD

The present invention relates to a substrate holding hand and a substrate conveying robot, and more particularly, it relates to a substrate holding hand and a substrate conveying robot each including a frame and a blade.

### BACKGROUND ART

Conventionally, a substrate holding hand including a frame and a blade is known. Such a hand is disclosed in Japanese Patent Laid-Open No. 2013-069914, for example.

Japanese Patent Laid-Open No. 2013-069914 discloses a substrate conveying hand (substrate holding hand) to convey a substrate. This substrate conveying hand includes a frame and a hand main body (blade) supported by the frame and supporting the substrate. In this substrate conveying hand, the width of the frame and the width of the hand main body are substantially the same as each other.

### PRIOR ART

### Patent Document

Patent Document 1: Japanese Patent Laid-Open No. 2013-069914

### SUMMARY OF THE INVENTION

### Problems to be Solved by the Invention

In the aforementioned substrate conveying hand described in Japanese Patent Laid-Open No. 2013-069914, the width of the frame and the width of the hand main body (blade) are substantially the same as each other, and thus the width of the frame is disadvantageously relatively large. On the other hand, in the substrate conveying hand described in Japanese Patent Laid-Open No. 2013-069914, there is conceivably a portion of the frame that is not effectively used to ensure the rigidity of the substrate conveying hand, and thus there is conceivably room for reducing the width of the frame while ensuring the rigidity (mechanical strength) of the substrate holding hand. Therefore, in the substrate conveying hand described in Japanese Patent Laid-Open No. 2013-069914, it is conceivably difficult to reduce the width of the frame while ensuring the rigidity (mechanical strength) of the substrate holding hand. When the width of the frame cannot be reduced, it is conceivably difficult to secure a space to arrange a component on the side of the frame, and it is conceivably difficult to easily maintain the component arranged on the side of the frame.

The present invention aims to provide a substrate holding hand and a substrate conveying robot each allowing the width of a frame to be reduced while the rigidity (mechanical strength) of a substrate holding hand is ensured, and thus allowing a space to be ensured to arrange a component on the side of the frame and allowing the component arranged on the side of the frame to be easily maintained.

### Means for Solving the Problems

A substrate holding hand according to a first aspect of the present invention includes a frame, a blade supported by the frame, a pair of front supports provided on a tip end side of the blade to support a substrate, and a pair of rear supports provided on a base end side of the blade to support the substrate. The frame, the pair of front supports, and the pair of rear supports are provided in a V-shape. In this description, the V-shape indicates a broader concept including not only a V-shape having an acute base end, but also a V-shape having a rounded base end like a U-shape.

A substrate conveying robot according to a second aspect of the present invention includes a substrate holding hand, and an arm to move the substrate holding hand. The substrate holding hand includes a frame, a blade supported by the frame, a pair of front supports provided on a tip end side of the blade to support a substrate, and a pair of rear supports provided on a base end side of the blade to support the substrate. The frame, the pair of front supports, and the pair of rear supports are provided in a V-shape.

### Effect of the Invention

According to the present invention, as described above, the frame, the pair of front supports, and the pair of rear supports are provided in a V-shape such that the occurrence of a portion of the frame that is not effectively used to ensure the rigidity of the substrate holding hand can be reduced or prevented. Consequently, the width of the frame can be reduced while the rigidity (mechanical strength) of the substrate holding hand is ensured, and thus a space can be ensured to arrange a component on the side of the frame, and the component arranged on the side of the frame can be easily maintained.

### BRIEF DESCRIPTION OF THE DRAWINGS

FIG. 1 is a diagram showing the configuration of a substrate conveying robot according to an embodiment of the present invention.

FIG. 2 is a perspective view showing the configuration of a substrate holding hand according to the embodiment of the present invention.

FIG. 3 is a plan view showing the configuration of the substrate holding hand according to the embodiment of the present invention.

FIG. 4 is a diagram for illustrating a relationship between a frame of the substrate holding hand, a front support, and a rear support according to the embodiment of the present invention.

FIG. 5 is a diagram for illustrating a relationship between a frame of the substrate holding hand, a front support, and a rear support according to a comparative example.

FIG. 6 is a diagram for illustrating the rigidity of a cantilever beam.

FIG. 7 is a diagram showing the substrate holding hand according to the embodiment of the present invention as viewed in an X1 direction.

FIG. 8 is a diagram showing the substrate holding hand according to the embodiment of the present invention as viewed in an X2 direction.

### MODES FOR CARRYING OUT THE INVENTION

An embodiment embodying the present invention is hereinafter described on the basis of the drawings.

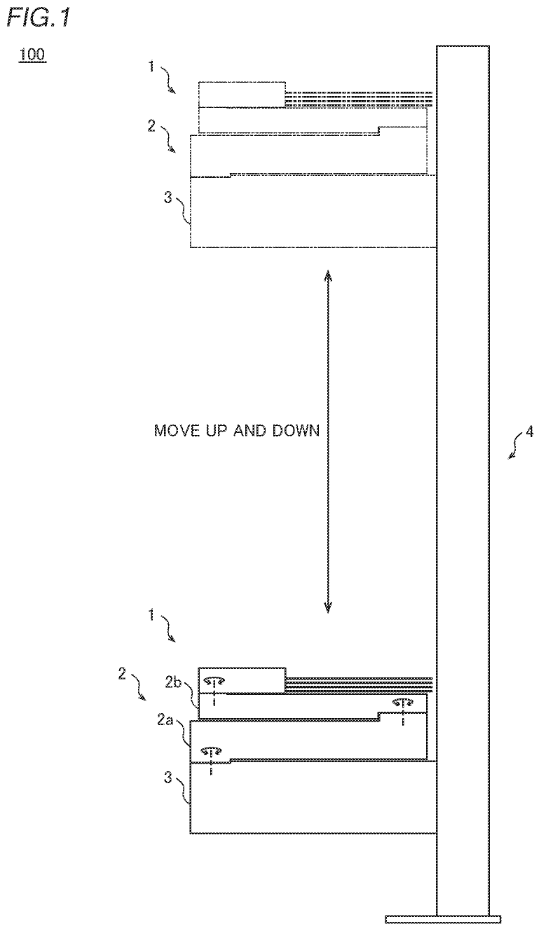

The configuration of a substrate conveying robot 100 according to this embodiment is now described with reference to FIGS. 1 to 8.

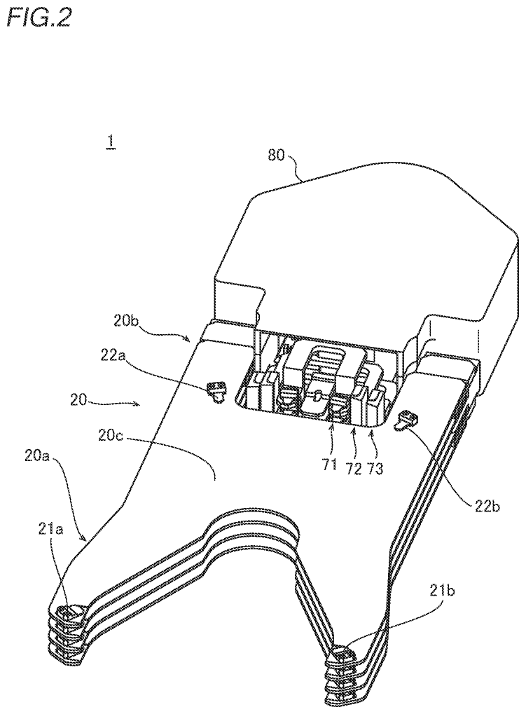

As shown in FIG. 1, the substrate conveying robot 100 includes a substrate holding hand 1 and an arm 2 that moves the substrate holding hand 1. As shown in FIGS. 2 to 4, the substrate holding hand 1 includes a frame 10, blades 20 supported by the frame 10, a pair of front supports 21a and 21b provided on the tip end 20a side (Y1 direction side) of each blade 20 to support a substrate (semiconductor wafer) W, and a pair of rear supports 22a and 22b provided on a base end 20b side (Y2 direction side) of each blade 20 to support the substrate W. The frame 10, the pair of front supports 21a and 21b, and the pair of rear supports 22a and 22b are provided in a V-shape. In this description, the V-shape indicates a broader concept including not only a V-shape having an acute base end, but also a V-shape having a rounded base end like a U-shape.

According to this embodiment, the frame 10, the pair of front supports 21a and 21b, and the pair of rear supports 22a and 22b are provided in a V-shape such that the width of the frame 10 can be reduced while the rigidity (mechanical strength) of the substrate holding hand 1 is ensured, and thus a space can be ensured to arrange a component on the side of the frame 10, and the component arranged on the side of the frame 10 can be easily maintained.

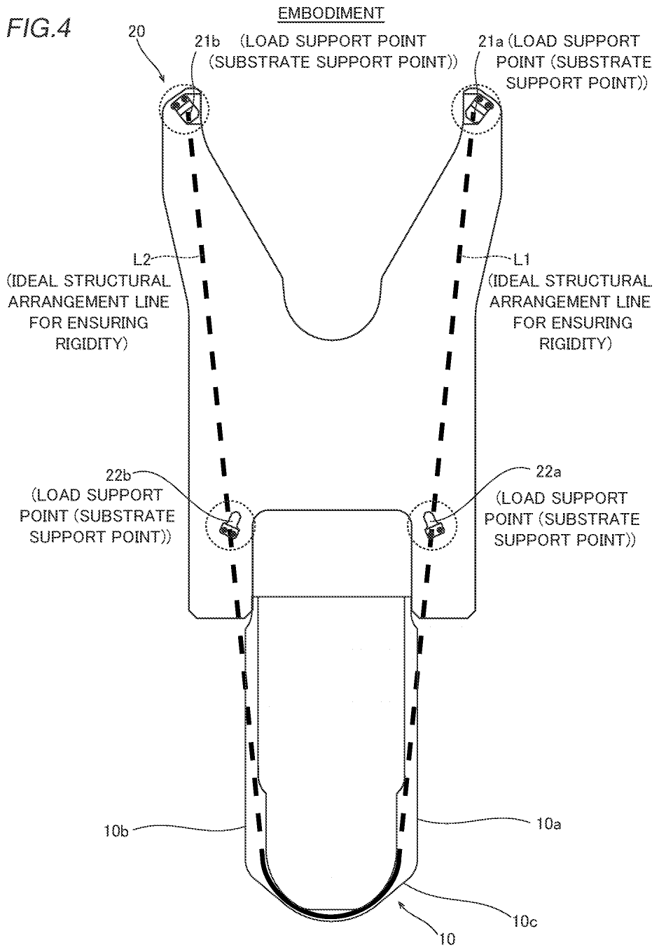

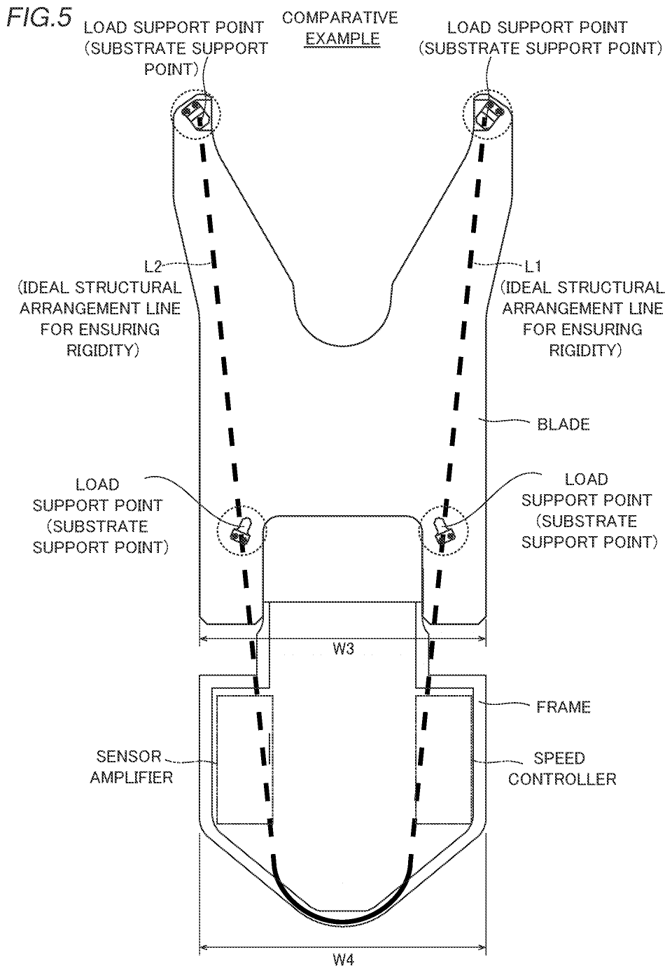

The frame 10 includes a pair of side walls 10a and One (10a) of the pair of side walls 10a and 10b is arranged on a first line L1 connecting a base end 10c of the frame 10, one (21a) of the pair of front supports 21a and 21b, and one (22a) of the pair of rear supports 22a and 22b, and extends along the first line L1. The other (10b) of the pair of side walls 10a and 10b is arranged on a second line L2 connecting the base end 10c of the frame the other (21b) of the pair of front supports 21a and 21b, and the other (22b) of the pair of rear supports 22a and 22b, and extends along the second line L2. Unlike the V-shaped configuration of the substrate holding hand 1 according to this embodiment shown in FIG. 4, in a comparative example shown in FIG. 5, a frame does not have a shape along a V-shaped line in a plan view, and the width W3 of a base end of a blade and the width W4 of the frame are the same as each other.

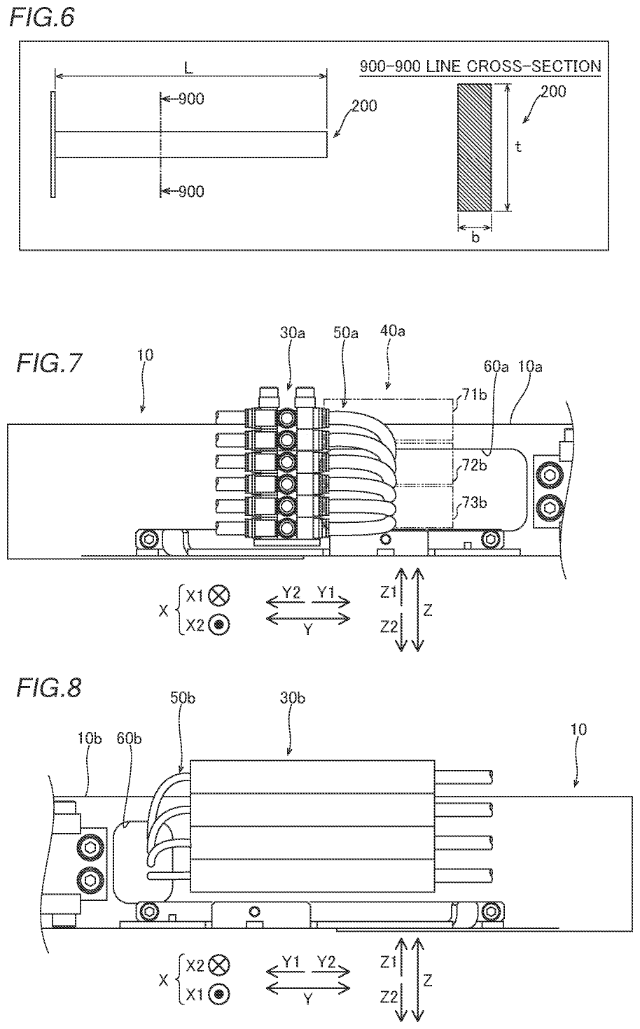

The rigidity of the substrate holding hand 1 is now described with reference to FIGS. 4 to 6. In a cantilever beam 200 shown in FIG. 6, the geometrical moment of inertia and the amount of deflection are expressed by the following equations (1) and (2), respectively:

1=b×t³/12 (1)

v=W/(3×E×1)×L³=4×W/{E×b×t³)×L³ (2)

where l represents a geometrical moment of inertia, b represents a width, t represents a thickness, v represents an amount of deflection, W represents a load, E represents a Young's modulus, and L represents a length.

As is clear from the above equations (1) and (2), the geometrical moment of inertia of the cantilever beam 200 is proportional to the cube of the thickness t, and the amount of deflection of the cantilever beam 200 is inversely proportional to the cube of the thickness t. That is, the rigidity of the cantilever beam 200 is greatly influenced by the thickness t.

Consider the rigidity of a substrate holding hand in the same way as the cantilever beam 200. In the substrate holding hand, a frame, which is a portion with a large thickness t, greatly contributes to the rigidity. In a substrate holding hand according to the comparative example shown in FIG. 5, side walls of the frame having a large thickness t are not arranged on a first line L1 and a second line L2, which are ideal structural arrangement lines for ensuring the rigidity. Therefore, in the substrate holding hand according to the comparative example shown in FIG. 5, the side walls of the frame having a large thickness t are not effectively used to ensure the rigidity.

On the other hand, in the substrate holding hand 1 according to this embodiment shown in FIG. 4, the side walls 10a and 10b of the frame 10 having a large thickness t are arranged on the first line L1 and the second line L2, which are ideal structural arrangement lines for ensuring the rigidity. Therefore, in the substrate holding hand 1 according to this embodiment shown in FIG. 4, the side walls 10a and 10b of the frame 10 having a large thickness t are effectively used to ensure the rigidity, unlike the substrate holding hand according to the comparative example shown in FIG. 5. Consequently, the substrate holding hand 1 according to this embodiment shown in FIG. 4 can achieve high rigidity.

The width W1 of the frame 10 is smaller than the widths W2 of the base ends 20b of the blades 20 in a direction (X direction) parallel to a direction in which the pair of front supports 21a and 21b are aligned.

The substrate holding hand 1 further includes frame outer components 30a and 30b arranged on the outside of the frame 10 in the direction (X direction) parallel to the direction in which the pair of front supports 21a and 21b are aligned.

The frame outer component 30a includes speed controllers for air cylinders. The frame outer component includes sensor amplifiers for sensors. The frame outer components may include only one of the sensor amplifiers for the sensors and the speed controllers for the air cylinders.

The frame outer components 30a and 30b are arranged on the outsides of the pair of side walls 10a and 10b, respectively, in the direction (X direction) parallel to the direction in which the pair of front supports 21a and 21b are aligned.

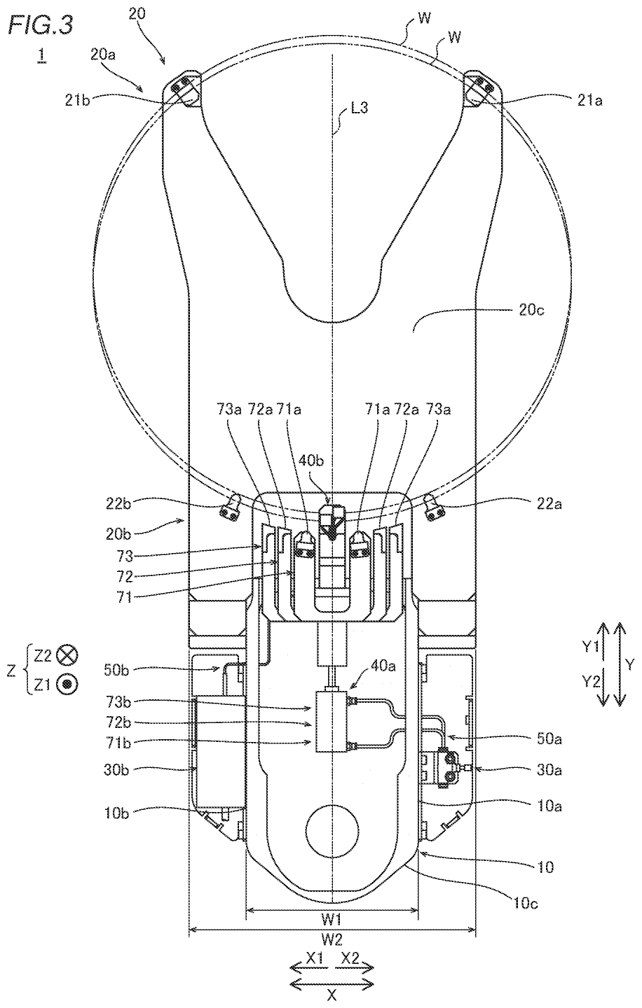

As shown in FIG. 7, an opening 60a is provided in the side wall 10a of the frame 10 to communicate the inside with the outside. As shown in FIGS. 3 and 7, connecting members (air pipes) 50a that connect the frame outer component 30a to a frame inner component (air cylinders) arranged on the inside of the frame 10 are inserted through the opening 60a. As shown in FIG. 8, an opening 60b is provided in the side wall 10b of the frame 10 to communicate the inside with the outside. As shown in FIGS. 3 and 8, connecting members (wiring) 50b that connect the frame outer component 30b to a frame inner component (substrate detection sensors) 40b arranged at a position corresponding to the inside of the frame 10 are inserted through the opening 60b.

The opening 60a also serves as an opening for maintenance of the frame inner component 40a.

As shown in FIGS. 3 and 7, the frame inner component includes the air cylinders. The opening 60a is positioned so as to overlap the air cylinders (frame inner component 40a) arranged on the inside of the frame 10, as viewed in the direction (X direction) parallel to the direction in which the pair of front supports 21a and 21b are aligned.

As shown in FIG. 1, the arm 2 is a horizontal articulated robot arm. The arm 2 includes a first arm 2a and a second arm 2b. The first arm 2a is rotatable with respect to a base 3, which is described below, with a first end as the center of rotation. Specifically, the first end of the first arm 2a is rotatably connected to the base 3 via a first joint. The second arm 2b is rotatable with respect to the first arm 2a with a first end as the center of rotation. Specifically, the first end of the second arm 2b is rotatably connected to a second end of the first arm 2a via a second joint. The substrate holding hand 1 is rotatably connected to a second end of the second arm 2b via a third joint. A drive mechanism including a servomotor corresponding to a drive source for rotary drive, a rotational position sensor that detects the rotational position of an output shaft of the servomotor, and a power transmission mechanism that transmits the output of the servomotor to the joint is provided at each of the first joint, the second joint, and the third joint.

The substrate conveying robot 100 further includes the base 3 to which the arm 2 is attached, and an arm elevating mechanism 4 to which the base 3 is attached. A first end of the base 3 is connected to the first end of the first arm 2a, and a second end of the base 3 is connected to the arm elevating mechanism 4. The arm elevating mechanism 4 moves the arm 2 up and down by moving the base 3 up and down. The arm elevating mechanism 4 includes a servomotor corresponding to a drive source for up-down drive, a rotational position sensor that detects the rotational position of an output shaft of the servomotor, and a power transmission mechanism that transmits the output of the servomotor to the base 3 (arm 2).

As shown in FIG. 2, the substrate holding hand 1 includes a plurality of (four) blades 20. That is, the substrate holding hand 1 can convey (hold) a plurality of (four) substrates W.

As shown in FIGS. 2 and 3, the substrate holding hand 1 includes the frame 10 and the blades 20. The frame 10 is a support that supports the blades 20. The frame 10 includes the pair of side walls 10a and 10b and the base end 10c connecting the pair of side walls 10a and 10b. The pair of side walls 10a and 10b are spaced apart from each other such that the wall surfaces thereof face each other in the direction (X direction) parallel to the direction in which the pair of front supports 21a and 21b are aligned. The pair of side walls 10a and 10b extend in a direction (Y direction) perpendicular to the direction in which the pair of front supports 21a and 21b are aligned and parallel to the main surfaces 20c of the blades 20. The base end 10c connects base ends (portions on the Y2 direction side) of the pair of side walls 10a and 10b. The base end 10c has a shape that is convexly curved toward the base end side (the Y2 direction side). The pair of side walls 10a and 10b and the base end 10c are provided in a U-shape, as viewed in a direction perpendicular to the main surfaces 20c of the blades 20.

The blades 20 are thin support plates that support the substrates W. Each of the blades 20 has a shape in which the tip end 20a side is bifurcated. In the blade 20, the pair of front supports 21a and 21b are distributed to the bifurcated portions. The pair of front supports 21a and 21b each have a plurality of (two) support surfaces at different heights. The pair of rear supports 22a and 22b each have a support surface at a height substantially the same as the heights of the support surfaces of the pair of front supports 21a and 21b on the lower side (Z2 direction side). The “height” refers to a distance from the main surfaces 20c of the blades 20 in the direction (Z direction) perpendicular to the main surfaces 20c of the blades 20.

The pair of front supports 21a and 21b and the pair of rear supports 22a and 22b are provided on the main surface 20c of each blade 20. The support surfaces of the pair of front supports 21a and 21b and the pair of rear supports 22a and 22b support the rear surface (the surface on the Z2 direction side) of the outer peripheral edge of the substantially circular substrate W from below.

In the direction (X direction) parallel to the direction in which the pair of front supports 21a and 21b are aligned, the pair of rear supports 22a and 22b are arranged inside (closer to a centerline L3 than) the pair of front supports 21a and 21b. Furthermore, in the direction (X direction) parallel to the direction in which the pair of front supports 21a and 21b are aligned, the pair of side walls 10a and 10b are arranged inside (closer to the centerline L3 than) the pair of rear supports 22a and 22b. Therefore, the first line L1 and the second line L2 (see FIG. 4) are inclined with respect to the centerline L3. Furthermore, the first line L1 and the second line L2 are inclined in opposite directions with respect to the centerline L3. The centerline L3 extends in the direction (Y direction) perpendicular to the direction in which the pair of front supports 21a and 21b are aligned and parallel to the main surfaces 20c of the blades 20.

The substrate holding hand 1 further includes a movable support unit 71 that moves back and forth to support the substrate W, and a first movable pressing unit 72 and a second movable pressing unit 73 that move back and forth to press the substrate W. The movable support unit 71 includes a pair of support members 71a that support the substrate W, and an air cylinder 71b corresponding to an actuator that moves the pair of support members 71a back and forth in the Y direction. In the movable support unit 71, the pair of support members 71a can be moved forward in the Y1 direction by the air cylinder 71b to be placed at support positions at which the pair of support members 71a support the substrate W. Furthermore, in the movable support unit 71, the pair of support members 71a can be moved backward in the Y2 direction by the air cylinder 71b to be placed at retracted positions at which the pair of support members 71a do not support the substrate W. The pair of support members 71a have support surfaces at heights substantially the same as the heights of the upper (Z1 direction side) support surfaces of the pair of front supports 21a and 21b. Each support surface of the pair of support members 71a supports the rear surface (the surface on the Z2 direction side) of the outer peripheral edge of the substantially circular substrate W from below.

The first movable pressing unit 72 includes a pair of pressing members 72a that press the substrate W, and an air cylinder 72b corresponding to an actuator that moves the pair of pressing members 72a back and forth in the Y direction. In the first movable pressing unit 72, the pair of pressing members 72a can be moved forward in the Y1 direction by the air cylinder 72b to press the substrate W. Furthermore, in the first movable pressing unit 72, the pair of pressing members 72a can be moved backward in the Y2 direction by the air cylinder 72b to be placed at retracted positions at which the pair of pressing members 72a do not press the substrate W.

The second movable pressing unit 73 includes a pair of pressing members 73a that press the substrate W, and an air cylinder 73b corresponding to an actuator that moves the pair of pressing members 73a back and forth in the Y direction. In the second movable pressing unit 73, the pair of pressing members 73a can be moved forward in the Y1 direction by the air cylinder 73b to press the substrate W. Furthermore, in the second movable pressing unit 73, the pair of pressing members 73a can be moved backward in the Y2 direction by the air cylinder 73b to be placed at retracted positions at which the pair of pressing members 73a do not press the substrate W.

In the substrate holding hand 1, the upper (Z1 direction side) support surfaces of the pair of front supports 21a and 21b and the support surfaces of the pair of support members 71a of the movable support unit 71 support the processed (washed) substrate W. The pair of pressing members 72a of the first movable pressing unit 72 press the processed (washed) substrate W supported by the upper (Z1 direction side) support surfaces of the pair of front supports 21a and 21b and the support surfaces of the pair of support members 71a of the movable support unit 71.

In the substrate holding hand 1, the lower (Z2 direction side) support surfaces of the pair of front supports 21a and 21b and the support surfaces of the pair of rear supports 22a and 22b support the substrate W prior to processing (washing). The pair of pressing members 73a of the second movable pressing unit 73 press the substrate W prior to processing (washing) supported by the lower (Z2 direction side) support surfaces of the pair of front supports 21a and 21b and the support surfaces of the pair of rear supports 22a and 22b. The pair of front supports 21a and 21b, the pair of rear supports 22a and 22b, the movable support unit 71, the first movable pressing unit 72, and the second movable pressing unit 73 are used properly for the substrate W prior to processing (washing) and the processed (washed) substrate W.

The air cylinder 71b of the movable support unit 71, the air cylinder 72b of the first movable pressing unit 72, and the air cylinder 73b of the second movable pressing unit 73 are arranged as the frame inner component 40a on the inside of the frame 10. The air cylinder 71b of the movable support unit 71, the air cylinder 72b of the first movable pressing unit 72, and the air cylinder 73b of the second movable pressing unit 73 are aligned in the direction (Z direction) perpendicular to the main surfaces 20c of the blades 20 on the inside of the frame 10. Specifically, the air cylinder 71b of the movable support unit 71, the air cylinder 72b of the first movable pressing unit 72, and the air cylinder 73b of the second movable pressing unit 73 overlap each other, as viewed in the direction (Z direction) perpendicular to the main surfaces 20c of the blades 20. Therefore, the air cylinders 71b, 72b, and 73b are not aligned in the width direction (X direction) of the frame 10, and thus the air cylinders 71b, 72b, and 73b can be compactly arranged in the width direction (X direction) of the frame 10.

The substrate holding hand 1 further includes a cover (casing) 80 (see FIG. 2) separately from the frame 10. The cover 80 covers the frame 10 and portions (portions arranged on the inside of the frame 10) of the movable support unit 71, the first movable pressing unit 72, and the second movable pressing unit 73.

As shown in FIG. 7, the frame outer component 30a includes the speed controllers (flow rate control valves) for the air cylinders 71b, 72b, and 73b. Two speed controllers are provided for each of the air cylinders 71b, 72b, and 73b. That is, a total of six speed controllers are provided. One of the two speed controllers is to control the flow rate of air during forward movement, and the other is to control the flow rate of air during backward movement. A plurality of speed controllers are aligned in the direction (Z direction) perpendicular to the main surfaces 20c of the blades 20. The plurality of speed controllers are provided in the vicinity of an end of the opening 60a. The plurality of speed controllers are exposed to the outside when the cover 80 is removed. Also, the connecting members 50a are flexible, bendable air pipes through which drive air to be supplied to the air cylinders 71b, 72b, and 73b flows.

As shown in FIG. 8, the frame outer component 30b includes the sensor amplifiers (amplifiers) for the substrate detection sensors (see FIG. 3) corresponding to the frame inner component 40b. The substrate detection sensors detect the presence or absence of the substrates W on the blades 20. The substrate detection sensors are reflective optical sensors, for example. A plurality of substrate detection sensors are provided. A plurality of sensor amplifiers are provided so as to correspond to the plurality of substrate detection sensors. The plurality of sensor amplifiers are aligned in the direction (Z direction) perpendicular to the main surfaces 20c of the blades 20. The plurality of sensor amplifiers are provided in the vicinity of an end of the opening 60b. The plurality of sensor amplifiers are exposed to the outside when the cover 80 is removed. The connecting members 50b are flexible, bendable wiring, and include electric wiring for signal transmission or optical fibers for light transmission.

As shown in FIG. 3, the frame outer component 30a and the frame outer component 30b are adjacent to the pair of side walls 10a and 10b in the direction (X direction) parallel to the direction in which the pair of front supports 21a and 21b are aligned. Furthermore, the frame outer component 30a and the frame outer component 30b do not protrude outside the base ends 20b of the blades 20 in the direction (X direction) parallel to the direction in which the pair of front supports 21a and 21b are aligned. That is, the frame outer component 30a and the frame outer component 30b are arranged substantially outside the width W1 of the frame 10, and substantially within the widths W2 of the base ends 20b of the blades 20 in the direction (X direction) parallel to the direction in which the pair of front supports 21a and 21b are aligned.

As shown in FIGS. 7 and 8, the openings 60a and 60b each have a substantially rectangular shape (rectangular shape with rounded corners). The opening 60a that also serves as an opening for maintenance of the frame inner component 40a has an opening area larger than the opening area of the opening 60b through which the connecting members 50b are only inserted.

### Advantages of this Embodiment

According to this embodiment, the following advantages are achieved.

According to this embodiment, as described above, the frame 10, the pair of front supports 21a and 21b, and the pair of rear supports 22a and 22b are provided in a V-shape such that the width of the frame 10 can be reduced while the rigidity (mechanical strength) of the substrate holding hand 1 is ensured, and thus a space can be ensured to arrange a component on the side of the frame 10 can be secured, and the component arranged on the side of the frame 10 can be easily maintained.

According to this embodiment, as described above, the frame 10 includes the pair of side walls 10a and 10b. One (10a) of the pair of side walls 10a and 10b is arranged on the first line L1 connecting the base end 10c of the frame 10, one (21a) of the pair of front supports 21a and 21b, and one (22a) of the pair of rear supports 22a and 22b, and extends along the first line L1. The other (10b) of the pair of side walls 10a and 10b is arranged on the second line L2 connecting the base end 10c of the frame 10, the other (21b) of the pair of front supports 21a and 21b, and the other (22b) of the pair of rear supports 22a and 22b, and extends along the second line L2. Accordingly, the pair of side walls 10a and 10b of the frame 10 can be arranged on the first line L1 and the second line L2, which are ideal structural arrangement lines for ensuring the rigidity of the substrate holding hand 1, and thus the pair of side walls 10a and 10b of the frame 10 can be effectively used to ensure the rigidity of the substrate holding hand 1. Consequently, the width W1 of the frame 10 can be easily reduced while the rigidity of the substrate holding hand 1 is easily ensured.

According to this embodiment, as described above, the width W1 of the frame 10 is smaller than the widths W2 of the base ends 20b of the blades 20 in the direction parallel to the direction in which the pair of front supports 21a and 21b are aligned. Accordingly, the width W1 of the frame 10 can be easily and reliably reduced.

According to this embodiment, as described above, the substrate holding hand 1 further includes the frame outer components 30a and 30b arranged on the outside of the frame 10 in the direction parallel to the direction in which the pair of front supports 21a and 21b are aligned. Accordingly, unlike a case in which the components are arranged on the inside of the frame 10, the frame outer components 30a and 30b can be easily accessed without being obstructed by the side walls 10a and 10b of the frame 10, for example, and thus the frame outer components 30a and 30b can be easily maintained. Furthermore, predetermined components (the sensor amplifiers and the speed controllers in this embodiment) among components to be arranged on the inside of the frame 10 can be arranged as the frame outer components 30a and 30b on the outside of the frame 10, and thus the number of components arranged on the inside of the frame 10 can be reduced. This advantage is particularly effective in the configuration according to this embodiment in which the width W1 of the frame 10 is reduced such that the inner area of the frame 10 is reduced.

According to this embodiment, as described above, the frame outer components 30a and 30b include the sensor amplifiers for the sensors and the speed controllers for the air cylinders. Accordingly, when the frame outer components 30a and 30b include the sensor amplifiers, an amplifier function adjustment by an operation on an operation button, for example, can be easily performed. When the frame outer components 30a and 30b include the speed controllers, a speed control function adjustment by an operation on an adjustment knob, for example, can be easily performed.

According to this embodiment, as described above, the frame 10 includes the pair of side walls 10a and 10b. The frame outer components 30a and 30b are arranged on the outsides of the pair of side walls 10a and 10b, respectively, in the direction parallel to the direction in which the pair of front supports 21a and 21b are aligned. Accordingly, more components can be arranged as the frame outer components 30a and 30b on the outside of the frame 10, and thus more frame outer components 30a and 30b can be easily maintained, and the number of components to be arranged on the inside of the frame 10 can be further reduced.

According to this embodiment, as described above, the side walls 10a and 10b of the frame 10 include the openings 60a and 60b to allow communication between the inside and the outside. The connecting members 50a and connecting the frame outer components 30a and 30b to the frame inner components 40a and 40b arranged on the inside of the frame 10 or at positions corresponding to the inside of the frame 10 are inserted through the openings 60a and 60b. Accordingly, even when the frame outer components 30a and 30b are arranged on the outside of the frame 10, the frame outer components 30a and 30b can be easily connected to the frame inner components 40a and 40b by the connecting members 50a and 50b inserted through the openings 60a and 60b, and the complexity of arrangement paths of the connecting members 50a and 50b can be reduced or prevented.

According to this embodiment, as described above, the opening 60a defines and functions as an opening for maintenance of the frame inner component 40a. Accordingly, effectively using the opening 60a for the connecting members 50a, the frame inner component 40a can be easily maintained.

According to this embodiment, as described above, the frame inner component 40a includes the air cylinders 71b, 72b, and 73b. The opening 60a overlaps the air cylinders 71b, 72b, and 73b arranged on the inside of the frame 10, as viewed in the direction parallel to the direction in which the pair of front supports 21a and 21b are aligned. Accordingly, the air cylinders 71b, 72b, and 73b can be easily operated through the openings 60a and 60b, and thus maintenance of the air cylinders such as maintenance of air pipes and electrical wiring can be easily performed.

### Modified Examples

The embodiment disclosed this time must be considered as illustrative in all points and not restrictive. The scope of the present invention is not shown by the above description of the embodiment but by the scope of claims for patent, and all modifications (modified examples) within the meaning and scope equivalent to the scope of claims for patent are further included.

For example, while the example in which the arm is a horizontal articulated robot arm has been shown in the aforementioned embodiment, the present invention is not limited to this. For example, the arm may be an arm other than a horizontal articulated robot arm, such as a vertical articulated robot arm.

While the example in which the substrate holding hand includes a plurality of blades has been shown in the aforementioned embodiment, the present invention is not limited to this. For example, the substrate holding hand may include one blade.

While the example in which the substrate holding hand includes four blades has been shown in the aforementioned embodiment, the present invention is not limited to this. For example, the substrate holding hand may include a plurality of blades other than four.

While the example in which each of the blades has a bifurcated shape has been shown in the aforementioned embodiment, the present invention is not limited to this. For example, each of the blades may have a shape other than a bifurcated shape.

While the example in which each of the blades can support two substrates at different heights has been shown in the aforementioned embodiment, the present invention is not limited to this. For example, each of the blades may be able to support only one substrate (able to support a substrate at only one height).

While the example in which the movable support unit is provided has been shown in the aforementioned embodiment, the present invention is not limited to this. For example, the movable support unit may not be provided.

While the example in which two pressing units, which are the first movable pressing unit and the second movable pressing unit, are provided has been shown in the aforementioned embodiment, the present invention is not limited to this. For example, only one movable pressing unit may be provided.

While the example in which the substrate holding hand includes the frame outer components has been shown in the aforementioned embodiment, the present invention is not limited to this. For example, the substrate holding hand may not have the frame outer components.

While the example in which the frame outer components are arranged on the outsides of the pair of side walls, respectively, has been shown in the aforementioned embodiment, the present invention is not limited to this. For example, the frame outer components may be arranged only on the outside of one side wall.

While the example in which the frame outer components include sensor amplifiers or speed controllers has been shown in the aforementioned embodiment, the present invention is not limited to this. For example, the frame outer components may include components other than sensor amplifiers and speed controllers.

### DESCRIPTION OF REFERENCE NUMERALS

1: substrate holding hand
2: arm
10: frame
10a, 10b: side wall
10c: base end
20: blade
20a: tip end
20b: base end
21a, 21b: front support
22a, 22b: rear support
30a, 30b: frame outer component
40a, 40b: frame inner component
50a, 50b: connecting member
60a, 60b: opening
100: substrate conveying robot
L1: first line
L2: second line
W1: width of the frame
W2: width of the base end of the blade

1. A substrate holding hand comprising:
a frame;
a blade supported by the frame;
a pair of front supports provided on a tip end side of the blade to support a substrate; and
a pair of rear supports provided on a base end side of the blade to support the substrate; wherein
the frame, the pair of front supports, and the pair of rear supports are provided in a V-shape.

2. The substrate holding hand according to claim 1, wherein
the frame includes a pair of side walls;
one of the pair of side walls is arranged on a first line connecting a base end of the frame, one of the pair of front supports, and one of the pair of rear supports, and extends along the first line; and
the other of the pair of side walls is arranged on a second line connecting the base end of the frame, the other of the pair of front supports, and the other of the pair of rear supports, and extends along the second line.

3. The substrate holding hand according to claim 1, wherein the frame has a width smaller than a width of a base end of the blade in a direction parallel to a direction in which the pair of front supports are aligned.

4. The substrate holding hand according to claim 3, further comprising:
a frame outer component arranged on an outside of the frame in the direction parallel to the direction in which the pair of front supports are aligned.

5. The substrate holding hand according to claim 4, wherein the frame outer component includes at least one of a sensor amplifier for a sensor or a speed controller for an air cylinder.

6. The substrate holding hand according to claim 4, wherein
the frame includes a pair of side walls; and
the frame outer component is arranged on an outside of each of the pair of side walls in the direction parallel to the direction in which the pair of front supports are aligned.

7. The substrate holding hand according to claim 4, wherein
the frame includes a side wall including an opening to allow communication between an inside and an outside; and
the substrate holding hand further comprises a connecting member connecting the frame outer component to a frame inner component arranged on an inside of the frame or at a position corresponding to the inside of the frame, the connecting member being inserted through the opening.

8. The substrate holding hand according to claim 7, wherein the opening defines and functions as an opening for maintenance of the frame inner component.

9. The substrate holding hand according to claim 8, wherein
the frame inner component includes an air cylinder; and
the opening overlaps the air cylinder arranged on the inside of the frame, as viewed in the direction parallel to the direction in which the pair of front supports are aligned.

10. A substrate conveying robot comprising:
a substrate holding hand; and
an arm to move the substrate holding hand; wherein the substrate holding hand includes:
a frame;
a blade supported by the frame;
a pair of front supports provided on a tip end side of the blade to support a substrate; and
a pair of rear supports provided on a base end side of the blade to support the substrate; and
the frame, the pair of front supports, and the pair of rear supports are provided in a V-shape.
